(19) United States
(12) Patent Application Publication
(10) Pub. No.: US 2025/0364507 A1
(43) Pub. Date: Nov. 27, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Shugo Suzuki, Hanno Saitama (JP); Yasutomo Sakurai, Kawasaki Kanagawa (JP); Hitoshi Imi, Yokohama Kanagawa (JP); Yutaka Horie, Mitaka Tokyo (JP)

(21) Appl. No.: 18/824,425

(22) Filed: Sep. 4, 2024

(30) Foreign Application Priority Data
May 21, 2024 (JP) 2024-082651

(51) Int. Cl. H01L 25/16; H01L 23/00; H01L 23/31; H01L 23/495

(52) U.S. Cl. CPC H01L 25/16; H01L 23/3107; H01L 23/49537; H01L 23/49589; H01L 24/48; H01L 2224/48137; H01L 2224/48175; H01L 2924/13064; H01L 2924/13091; H01L 2924/19041; H01L 2924/19102

(57) ABSTRACT

First and second switches are electrically connected. A capacitor includes first and second terminals and a capacitor having an end electrically connected to the first terminal and another end electrically connected to the second terminal. The first and second terminals are electrically connected to the first and second switches, respectively. The capacitor is located above the first and second switches along a first direction. A width of the capacitor in a second direction that is a direction connecting the end and the another end of the capacitor is larger than a width of a set of the first and second switches in the second direction. The first switch and the second switch are arranged in the second direction.

### CROSS-REFERENCE TO RELATED APPLICATION

This application is based upon and claims the benefit of priority from Japanese Patent Application No. 2024-082651, filed May 21, 2024, the entire contents of which are incorporated herein by reference.

### FIELD

Embodiments described herein relate generally to a semiconductor device.

### BACKGROUND

A semiconductor device including a semiconductor chip and a resin for sealing the semiconductor chip is known. The semiconductor device is required to have high speed response and be miniaturized.

### BRIEF DESCRIPTION OF DRAWINGS

FIG. 1 is a perspective view showing an example of a structure of a semiconductor device according to a first embodiment.

FIG. 2 is a perspective view showing an example of a structure of the semiconductor device according to the first embodiment as viewed from below.

FIG. 3 shows an example of a cross-sectional structure of the semiconductor device according to the first embodiment, and is a cross-sectional view taken along line III-III of FIG. 1.

FIG. 4 shows an example of a cross-sectional structure of the semiconductor device according to the first embodiment, and is a cross-sectional view taken along line IV-IV of FIG. 3.

FIG. 5 is a circuit diagram showing an example of an electric circuit of the semiconductor device according to the first embodiment.

FIG. 6 is a conceptual diagram showing an example of a case where a high-frequency signal is input to the semiconductor device according to the first embodiment.

### DETAILED DESCRIPTION

In general, according to one embodiment, a semiconductor device includes a first switch, a second switch, and a capacitor. The second switch is electrically connected to the first switch. The capacitor includes a first terminal, a second terminal, and a capacitor having an end electrically connected to the first terminal and another end electrically connected to the second terminal. The first terminal is electrically connected to the first switch. The second terminal is electrically connected to the second switch. The capacitor is located above the first switch and the second switch along a first direction. A width of the capacitor in a second direction that is a direction connecting the end and the another end of the capacitor is larger than a width of a set of the first switch and the second switch in the second direction. The first switch and the second switch are arranged in the second direction.

Embodiments will now be described with reference to the figures.

The figures are schematic, and the relation between the thickness and the area of a plane of a layer and the ratio of thicknesses of layers may differ from those in actuality. The figures may include components which differ in relations and/or ratios of dimensions in different figures.

The embodiments will be described using an X-Y-Z orthogonal coordinate system. A plus direction of a vertical axis in a drawing may be referred to as an upper side, and a minus direction of the vertical axis may be referred to as a lower side. A plus direction of a horizontal axis in a drawing may be referred to as a right side, and a minus direction of the horizontal axis may be referred to as a left side. That is, in a plan view showing an X-Y plane (referred to as an X-Y plane view, the same applying hereinafter), an upper side of the X-Y plane represents a +Y direction, a lower side of the X-Y plane represents a −Y direction, a right side of the X-Y plane represents a +X direction, and a left side of the X-Y plane represents a −X direction.

In the plan view, hatching lines are appropriately added for improved visibility of the drawings. The hatching lines added to the plan view are not necessarily related to materials or characteristics of the components to which the hatching lines are added. In the cross-sectional view, the components such as an insulator layer, a substrate, wiring, and a terminal are omitted as appropriate for improved visibility.

The specification and the claims, when mentioning that a particular (first) component is “coupled” to another (second) component, intend to cover both the form of the first component directly coupled to the second component and the form of the first component coupled to the second component via one or more components which are always or selectively conductive.

### 1. First Embodiment

A semiconductor device according to a first embodiment will be described.

The semiconductor device according to the first embodiment is a device including a semiconductor chip, a resin for sealing the semiconductor chip, and an external connection terminal. Examples of an application form of the semiconductor device according to the first embodiment include a switching apparatus for an automobile. The semiconductor device includes, for example, a GaN module.

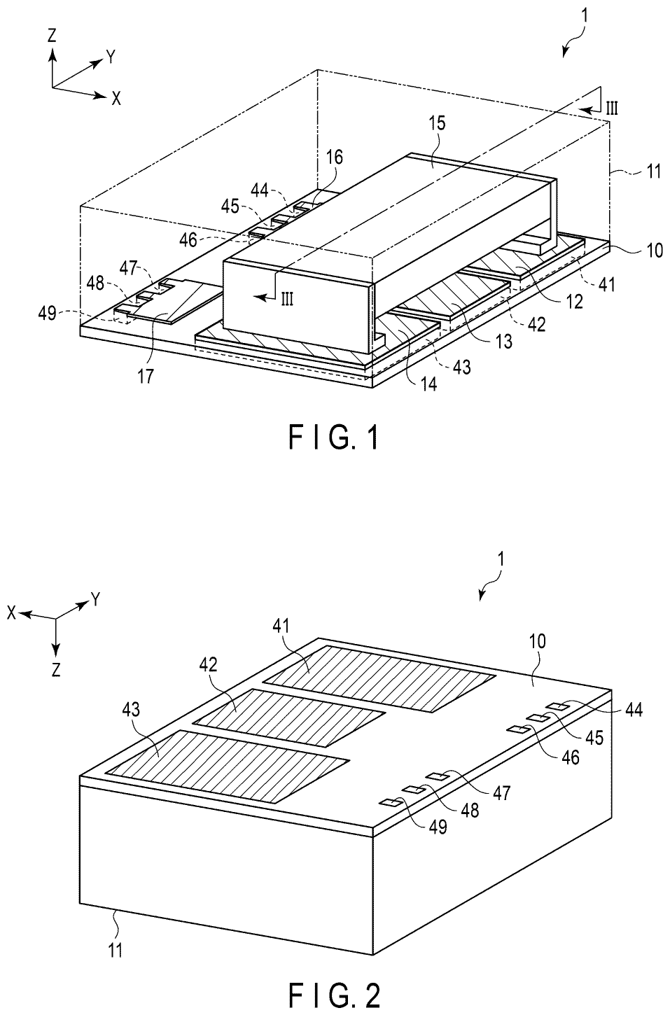

FIG. 1 is the perspective view showing the example of the structure of the semiconductor device according to the first embodiment.

A semiconductor device 1 includes a package substrate 10, a case 11, a first lead frame 12, a second lead frame 13, a third lead frame 14, a capacitor 15, a first control driver 16, a second control driver 17, and external connection terminals 41 to 49. In FIG. 1, the case 11 is indicated by an alternate long and two short dashed line frame in order to ensure visibility.

The package substrate 10 is a support of the semiconductor device 1. The package substrate 10 has a flat plate shape, for example, a quadrilateral shape. The package substrate 10 constitutes a lower portion of a container of the semiconductor device 1. The package substrate 10 includes, for example, ceramics.

The case 11 is an insulator having a square tube shape. The case 11 is located on an upper surface of the package substrate 10. The case 11 constitutes a side portion and an upper portion of the container of the semiconductor device 1. The case 11 is fixed to the package substrate 10. The case 11 is also called an insulating resin, a sealing resin, or a mold resin.

In the following description, a surface on which the package substrate 10 spreads is referred to as the X-Y plane. A longitudinal direction of the package substrate 10 is referred to as a Y direction, and a direction orthogonal to the Y direction is referred to as an X direction. A direction from the package substrate 10 toward the case 11 is referred to as a Z direction. The Z direction is also an upward direction.

The first lead frame 12 is disposed on the package substrate 10. The first lead frame 12 has a flat plate shape, for example, a quadrilateral shape. The first lead frame 12 includes, for example, copper (Cu).

The second lead frame 13 is disposed on the package substrate 10. The second lead frame 13 has the flat plate shape, for example, the quadrilateral shape. The second lead frame 13 includes, for example, the copper.

The third lead frame 14 is disposed on the package substrate 10. The third lead frame 14 has the flat plate shape, for example, the quadrilateral shape. The third lead frame 14 includes, for example, the copper.

The first control driver 16 is disposed on the package substrate 10. The first control driver 16 has a flat plate shape. The first control driver 16 has, for example, a structure in a quadrilateral shape to which a plurality of protrusions are added. FIG. 1 and the following description are based on an example in which the number of the protrusions is three. The protrusions are arranged in the Y direction, for example, on a side close to a side surface of the case 11. The first control driver 16 may not have the protrusions depending on design. The first control driver 16 includes, for example, the copper.

The second control driver 17 is disposed on the package substrate 10. The second control driver 17 has the flat plate shape. The second control driver 17 has, for example, the structure in the quadrilateral shape to which the plurality of protrusions are added. FIG. 1 and the following description are based on an example in which the number of the protrusions is three. The protrusions are arranged in the Y direction, for example, on a side close to a side surface of the case 11. The second control driver 17 may not have the protrusions depending on the design. The second control driver 17 includes, for example, the copper. Here, the control driver is also referred to as a control device.

The first lead frame 12, the second lead frame 13, and the third lead frame 14 are arranged in this order along the −Y direction, for example. The first control driver 16 is disposed near the first lead frame 12 and the second lead frame 13. The second control driver 17 is disposed near the third lead frame 14. Details will be described later.

The capacitor 15 functions as a decoupling capacitor (or, a bypass capacitor) in the semiconductor device 1. The capacitor 15 is, for example, a multi-layer ceramic capacitor (MLCC). The capacitor 15 is disposed above the first lead frame 12, the second lead frame 13, and the third lead frame 14. An end of the capacitor 15 is electrically connected to the first lead frame 12. The other end of the capacitor 15 is electrically connected to the third lead frame 14. As the capacitor 15, for example, a silicon capacitor or a film capacitor may be used as long as the capacitor 15 functions as the decoupling capacitor. Details of the capacitor 15 will be described later.

Each of the external connection terminals 41 to 49 is a terminal that electrically connects a device outside the semiconductor device 1 and an inner portion of the semiconductor device 1. FIG. 1 and the following description are based on an example in which the semiconductor device 1 has the external connection terminals on a lower surface of the semiconductor device 1.

The external connection terminals 41 to 49 will be described with reference to FIG. 2. FIG. 2 is a perspective view showing an example of a structure of the semiconductor device 1 according to the first embodiment as viewed from below (or, a −Z direction).

The external connection terminal 41 is disposed on a lower surface of the first lead frame 12, and a lower surface of the external connection terminal 41 is exposed on a lower surface of the package substrate 10. The external connection terminal 41 is electrically connected to the first lead frame 12. The external connection terminal 41 has a flat plate shape, for example, a quadrilateral shape.

The external connection terminal 42 is disposed on a lower surface of the second lead frame 13, and a lower surface of the external connection terminal 42 is exposed on the lower surface of the package substrate 10. The external connection terminal 42 is electrically connected to the second lead frame 13. The external connection terminal 42 has the flat plate shape, for example, the quadrilateral shape.

The external connection terminal 43 is disposed on a lower surface of the third lead frame 14, and a lower surface of the external connection terminal 43 is exposed on the lower surface of the package substrate 10. The external connection terminal 43 is electrically connected to the third lead frame 14. The external connection terminal 43 has the flat plate shape, for example, the quadrilateral shape.

The external connection terminals 41 to 43 are arranged in this order along the −Y direction, for example.

The external connection terminals 44 to 46 are disposed on a lower surface of the first control driver 16, and a lower surface of each of the external connection terminals 44 to 46 is exposed on the lower surface of the package substrate 10. Each of the external connection terminals 44 to 46 is electrically connected to the first control driver 16. Each of the external connection terminals 44 to 46 has a flat plate shape, for example, a quadrilateral shape. The external connection terminals 44 to 46 are disposed, for example, on a lower surface of each of the three protrusions included in the first control driver 16. The external connection terminals 44 to 46 are arranged in this order along the −Y direction, for example.

The external connection terminals 47 to 49 are disposed on a lower surface of the second control driver 17, and a lower surface of each of the external connection terminals 47 to 49 is exposed on the lower surface of the package substrate 10. Each of the external connection terminals 47 to 49 is electrically connected to the second control driver 17. Each of the external connection terminals 47 to 49 has the flat plate shape, for example, the quadrilateral shape. The external connection terminals 47 to 49 are disposed, for example, on the lower surface of each of the three protrusions included in the second control driver 17. The external connection terminals 47 to 49 are arranged in this order along the −Y direction, for example.

Positions of the external connection terminals of the semiconductor device 1 are not limited to the lower surface of the semiconductor device 1, and for example, the external connection terminals may be located on a side surface of the semiconductor device 1. Further, the number of external connection terminals included in each of the first lead frame 12, the second lead frame 13, the third lead frame 14, the first control driver 16, and the second control driver 17 is designed to be any number, and is not limited to the illustration of FIGS. 1 and 2.

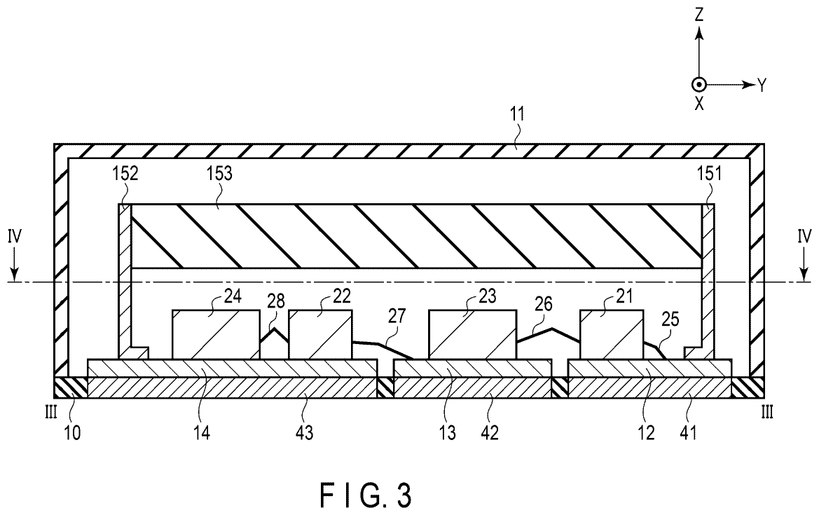

FIG. 3 is the example of the cross-sectional structure of the semiconductor device according to the first embodiment, and is the cross-sectional view taken along line III-III of FIG. 1.

As illustrated in FIG. 3, the semiconductor device 1 further includes a first GaN transistor 21, a second GaN transistor 22, a first P-type MOSFET 23, a second P-type MOSFET 24, and a plurality of bonding wires 25 to 28.

The first GaN transistor 21 and the second GaN transistor 22 include, for example, a normally-on type GaN high electron mobility transistor (HEMT).

The first P-type MOSFET 23 and the second P-type MOSFET 24 are p-type metal-oxide-semiconductor (MOS) transistors.

As described above, the first lead frame 12 is disposed on the external connection terminal 41. The second lead frame 13 is disposed on the external connection terminal 42. The third lead frame 14 is disposed on the external connection terminal 43. The first GaN transistor 21 is disposed on the first lead frame 12.

The first P-type MOSFET 23 is disposed on the second lead frame 13. The first P-type MOSFET 23 controls the first GaN transistor 21 in a manner that the first GaN transistor 21 exhibits a normally-off behavior.

The second GaN transistor 22 and the second P-type MOSFET 24 are disposed on the third lead frame 14. The second P-type MOSFET 24 controls the second GaN transistor 22 in a manner that the second GaN transistor 22 exhibits a normally-off behavior.

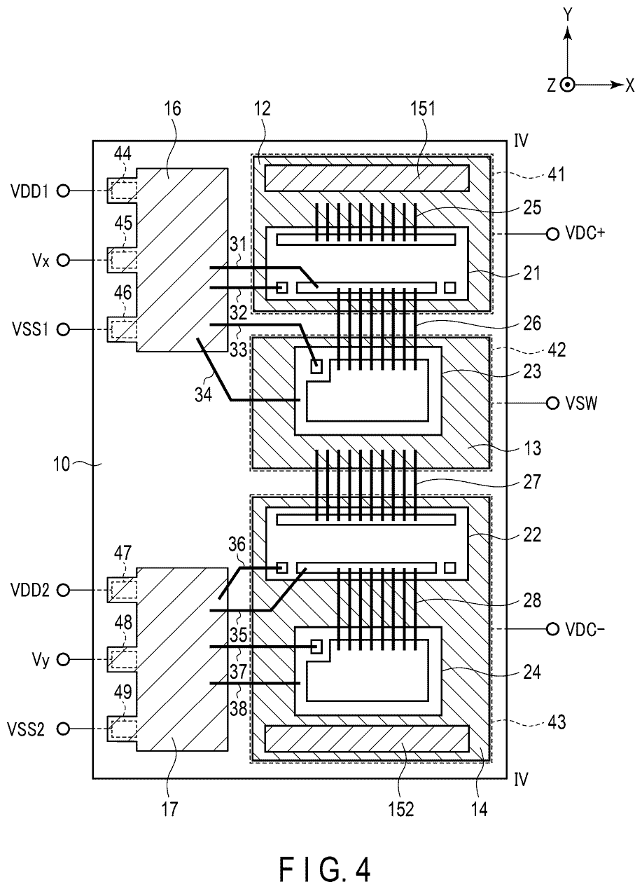

The plurality of bonding wires 25 to 28 will be described later with reference to FIG. 4.

The capacitor 15 includes, for example, a first terminal 151, a second terminal 152, and a capacitor portion 153. The first terminal 151 is disposed on and electrically connected to the first lead frame 12. The second terminal 152 is disposed on and electrically connected to the second lead frame 13.

The capacitor portion 153 has an end electrically connected to the first terminal 151, and the other end electrically connected to the second terminal 152. The capacitor portion 153 is disposed above the first GaN transistor 21, the second GaN transistor 22, the first P-type MOSFET 23, and the second P-type MOSFET 24. The capacitor portion 153 extends in the Y direction and is sandwiched between the first terminal 151 and the second terminal 152. Hereinafter, a set of the first GaN transistor 21, the second GaN transistor 22, the first P-type MOSFET 23, and the second P-type MOSFET 24 may be referred to as a GaN transistor group TR.

A width of the capacitor portion 153 in the Y direction is larger than a width of the GaN transistor group TR in the Y direction. In other words, in the X-Y plane view (or, a top view), the capacitor portion 153 covers the GaN transistor group TR in the Y direction. In other words, in the Y direction, an end portion of capacitor portion 153 on the first terminal 151 side is located on a +Y side with respect to an end portion of the first GaN transistor 21 on the first terminal 151 side, and is located on a side closer to a side surface of the case 11 on the +Y side. Similarly, an end portion of the capacitor portion 153 on the second terminal 152 side is located on a −Y side with respect to an end portion of the second P-type MOSFET 24 on the second terminal 152 side, and is located on a side closer to a side surface of the case 11 on the −Y side.

The width of the GaN transistor group TR in the Y direction can also be said to be a distance in the Y direction between an end on the +Y direction side of an element located at a farthest end on the +Y direction side, and an end on the −Y direction side of an element located at a farthest end on the −Y direction side opposite to the +Y direction, among the first GaN transistor 21, the second GaN transistor 22, the first P-type MOSFET 23, and the second P-type MOSFET 24 arranged in the Y direction.

Further, the width of the GaN transistor group TR in the Y direction can also be said to be a total length in the Y direction of a width of the first GaN transistor 21, a width of the second GaN transistor 22, a width of the first P-type MOSFET 23, a width of the second P-type MOSFET 24, and a distance between adjacent elements among the first GaN transistor 21, the second GaN transistor 22, the first P-type MOSFET 23, and the second P-type MOSFET 24 arranged in the Y direction.

Further, the width of the GaN transistor group TR in the Y direction can also be said to be a total length of the width of the first GaN transistor 21, the width of the second GaN transistor 22, the width of the first P-type MOSFET 23, the width of the second P-type MOSFET 24, a distance between the first GaN transistor 21 and the first P-type MOSFET 23, a distance between the first P-type MOSFET 23 and the second GaN transistor 22, and a distance between the second GaN transistor 22 and the second P-type MOSFET 24 in the Y direction.

For example, a width of the capacitor portion 153 in the X direction may be equal to or larger than a width of the GaN transistor group TR in the X direction. In other words, the capacitor portion 153 may cover the GaN transistor group TR in the X-Y plane view (or, the top view).

The width of the GaN transistor group TR in the X direction can also be said to be a distance in the X direction between an end on the +X direction side of an element located at a farthest end on the +X direction side and an end on the −X direction side of an element located at a farthest end on the −X direction side opposite to the +X direction among the first GaN transistor 21, the second GaN transistor 22, the first P-type MOSFET 23, and the second P-type MOSFET 24.

An example in which the width of the capacitor portion 153 in the X direction is smaller than the width of the GaN transistor group TR in the X direction will be described later.

Configurations of the transistors included in the semiconductor device 1 are not limited to the above-described configurations. For example, the first GaN transistor 21 may be a normally-off type GaN transistor. In that case, the semiconductor device 1 does not have the first P-type MOSFET 23. Similarly, the second GaN transistor 22 may also be the normally-off GaN transistor. In that case, the semiconductor device 1 does not have the second P-type MOSFET 24. Even in such configuration, the width of the capacitor portion 153 in the Y direction is larger than a width of a set of the first GaN transistor 21 and the second GaN transistor 22 in the Y direction.

Further, a set of the first GaN transistor 21 and the first P-type MOSFET 23 may be replaced with a transistor other than the GaN transistor, and for example, may be replaced with a switching element. Similarly, a set of the second GaN transistor 22 and the second P-type MOSFET 24 may be replaced with a transistor other than the GaN transistor, and for example, may be replaced with a switching element. The first P-type MOSFET 23 and/or the second P-type MOSFET 24 may be replaced with a transistor other than the P-type MOSFETs.

FIG. 4 shows an example of the cross-sectional structure of the semiconductor device according to the first embodiment, and is the cross-sectional view taken along line IV-IV of FIG. 3. As illustrated in FIG. 4, the semiconductor device 1 further includes bonding wires 31 to 38.

In the X-Y plane view (or, the top view), for example, the first terminal 151, the first GaN transistor 21, the first P-type MOSFET 23, the second GaN transistor 22, the second P-type MOSFET 24, and the second terminal 152 are arranged in this order along the −Y direction.

The first control driver 16 controls the first GaN transistor 21 and the first P-type MOSFET 23. The first control driver 16 is disposed near the first GaN transistor 21 and the first P-type MOSFET 23, whereby parasitic inductance depending on a length of a current path can be reduced. Therefore, the first control driver 16 is disposed near the first lead frame 12 and the second lead frame 13 within a range in which current flowing through the capacitor 15 does not adversely affect the first control driver 16. In other words, for example, a distance between the first control driver 16 and the capacitor 15 in an X-Y plane direction is a minimum distance at which the current flowing through the capacitor 15 does not adversely affect the first control driver 16.

The second control driver 17 controls the second GaN transistor 22 and the second P-type MOSFET 24. The second control driver 17 is disposed near the second GaN transistor 22 and the second P-type MOSFET 24, whereby the parasitic inductance depending on a length of a current path can be reduced. Therefore, the second control driver 17 is disposed near the third lead frame 14 within a range in which the current flowing through the capacitor 15 does not adversely affect the second control driver 17. In other words, for example, a distance between the second control driver 17 and the capacitor 15 in the X-Y plane direction is a minimum distance at which the current flowing through the capacitor 15 does not adversely affect the second control driver 17.

An end of the first GaN transistor 21 is electrically connected to the first lead frame 12 via a plurality of bonding wires 25. The plurality of bonding wires 25 are connected in parallel between the end of the first GaN transistor 21 and the first lead frame 12. The other end of the first GaN transistor 21 is electrically connected to an end of the first P-type MOSFET 23 via a plurality of bonding wires 26. The plurality of bonding wires 26 are connected in parallel between the other end of the first GaN transistor 21 and the end of the first P-type MOSFET 23.

The other end of the first GaN transistor 21 is connected to the first control driver 16 via a bonding wire 31. The number of the bonding wire 31 may be more than one, and in this case, the bonding wires are connected in parallel between the other end of the first GaN transistor 21 and the first control driver 16. A gate end of the first GaN transistor 21 is connected to the first control driver 16 via a bonding wire 32. The number of the bonding wire 32 may be more than one, and in this case, the bonding wires 32 are connected in parallel between the gate end of the first GaN transistor 21 and the first control driver 16.

The other end of the first P-type MOSFET 23 is electrically connected to the second lead frame 13 via, for example, a back surface of the first P-type MOSFET 23.

The other end of the first P-type MOSFET 23 is connected to the first control driver 16 via a bonding wire 33. The number of the bonding wire 33 may be more than one, and in this case, the bonding wires 33 are connected in parallel between the other end of the first P-type MOSFET 23 and the first control driver 16. A gate end of the first P-type MOSFET 23 is connected to the first control driver 16 via a bonding wire 34. The number of the bonding wire 34 may be more than one, and in this case, the bonding wires 34 are connected in parallel between the gate end of the first P-type MOSFET 23 and the first control driver 16.

An end of the second GaN transistor 22 is electrically connected to the second lead frame 13 via a plurality of bonding wires 27. The plurality of bonding wires 27 are connected in parallel between the end of the second GaN transistor 22 and the second lead frame 13. The other end of the second GaN transistor 22 is electrically connected to an end of the second P-type MOSFET 24 via a plurality of bonding wires 28. The plurality of bonding wires 28 are connected in parallel between the other end of the second GaN transistor 22 and the end of the second P-type MOSFET 24.

The other end of the second GaN transistor 22 is connected to the second control driver 17 via a bonding wire 35. The number of the bonding wire 35 may be more than one, and in this case, the bonding wires 35 are connected in parallel between the another end of the second GaN transistor 22 and the second control driver 17. A gate end of the second GaN transistor 22 is connected to the second control driver 17 via a bonding wire 36. The number of the bonding wire 36 may be more than one, and in this case, the bonding wires 36 are connected in parallel between the gate end of the second GaN transistor 22 and the second control driver 17.

The other end of the second P-type MOSFET 24 is electrically connected to the third lead frame 14 via, for example, a back surface of the second P-type MOSFET 24.

The other end of the second P-type MOSFET 24 is connected to the second control driver 17 via, for example, a bonding wire 37. The number of the bonding wire 37 may be more than one, and in this case, the bonding wires 37 are connected in parallel between the other end of the second P-type MOSFET 24 and the second control driver 17. A gate end of the second P-type MOSFET 24 is connected to the second control driver 17 via, for example, a bonding wire 38. The number of the bonding wire 38 may be more than one, and in this case, the bonding wires 38 are connected in parallel between the gate end of the second P-type MOSFET 24 and the second control driver 17.

The capacitor 15 may or may not be connected to the second control driver 17 via, for example, a bonding wire.

The external connection terminal 41 is an input terminal. The first lead frame 12 receives, for example, an input signal VDC+ from the outside via the external connection terminal 41.

The external connection terminal 42 is an output terminal. The second lead frame 13 outputs, for example, an output signal VSW to the outside via the external connection terminal 42.

The external connection terminal 43 is an input terminal. The third lead frame 14 receives, for example, an input signal VDC− from the outside via the external connection terminal 43. The input signal VDC− is smaller than the input signal VDC+ and includes, for example, a voltage of 0 V.

The first control driver 16 is connected to a node of an external voltage VDD1 via the external connection terminal 44, for example. For example, a constant voltage VDD1 is applied to the node of the voltage VDD1.

The first control driver 16 receives, for example, a control signal Vx from the outside via the external connection terminal 45. The control signal Vx is, for example, a signal for controlling the first control driver 16.

The first control driver 16 is connected to a node of an external voltage VSS1 via the external connection terminal 46, for example. For example, a constant voltage VSS1 is applied to the node of the voltage VSS1. The voltage VSS1 is smaller than the voltage VDD1, and is, for example, 0 V.

The second control driver 17 is connected to a node of an external voltage VDD2 via the external connection terminal 47, for example. For example, a constant voltage VDD2 is applied to the node of the voltage VDD2.

The second control driver 17 receives, for example, a control signal Vy from the outside via the external connection terminal 48. The control signal Vy is, for example, a signal for controlling the second control driver 17.

The second control driver 17 is connected to a node of an external voltage VSS2 via the external connection terminal 49, for example. For example, a constant voltage VSS2 is applied to the node of the voltage VSS2. The voltage VSS2 is smaller than the voltage VDD2, and is, for example, 0 V.

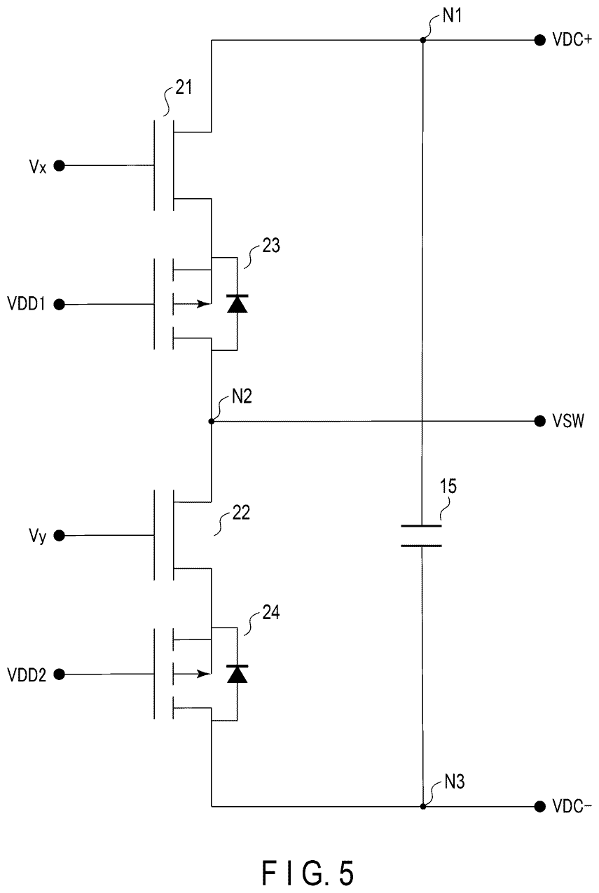

The shapes (also referred to as planar shapes) of the first lead frame 12, the second lead frame 13, the third lead frame 14, the first control driver 16, and the second control driver 17 illustrated in FIG. 4 along the X-Y plane are merely examples, and may be any planar shape as long as an electric circuit illustrated in FIG. 5 is achieved.

Connection of the bonding wires 31 to 38 illustrated in FIG. 4 is merely an example, and other connection structures may be included as long as the electric circuit illustrated in FIG. 5 is achieved.

The number of the external connection terminals included in and the signal received by each of the first control driver 16 and the second control driver 17 are merely examples, and other configurations may be possible as long as the first GaN transistor 21, the second GaN transistor 22, the first P-type MOSFET 23, and the second P-type MOSFET 24 can be controlled.

FIG. 5 is the circuit diagram showing an example of the electric circuit of the semiconductor device according to the first embodiment.

A drain end of the first GaN transistor 21 is connected to a node N1. The node N1 corresponds to the external connection terminal 41, and receives, for example, the input signal VDC+.

A source end of the first GaN transistor 21 is connected to a drain end of the first P-type MOSFET 23.

The gate end of the first GaN transistor 21 is connected to, for example, a node corresponding to the external connection terminal 45 of the first control driver 16, and receives, for example, the control signal Vx.

A source end of the first P-type MOSFET 23 is connected to a node N2. The node N2 corresponds to the external connection terminal 42, and outputs, for example, the output signal VSW.

The gate end of the first P-type MOSFET 23 is connected to, for example, the node of the voltage VDD1 corresponding to the external connection terminal 44.

A drain end of the second GaN transistor 22 is connected to the node N2.

A source end of the second GaN transistor 22 is connected to a drain end of the second P-type MOSFET 24.

The gate end of the second GaN transistor 22 is connected to, for example, a node corresponding to the external connection terminal 48 of the second control driver 17, and receives, for example, the control signal Vy.

A source end of the second P-type MOSFET 24 is connected to a node N3. The node N3 corresponds to the external connection terminal 43, and receives, for example, the input signal VDC−.

The gate end of the second P-type MOSFET 24 is connected to, for example, the node of the voltage VDD2 corresponding to the external connection terminal 47.

The capacitor 15 has an end connected to the node N1, and the other end connected to the node N3.

The first GaN transistor 21 and the first P-type MOSFET 23 are cascode-connected, for example. The second GaN transistor 22 and the second P-type MOSFET 24 are cascode-connected, for example.

In this way, control of an on operation and an off operation of the semiconductor device 1 is performed by the control signal Vx and the control signal Vy. In other words, the on operation and the off operation of the semiconductor device 1 are controlled by the first GaN transistor 21 and the second GaN transistor 22. The first P-type MOSFET 23 is turned on when the first GaN transistor 21 starts operating, and then, continues the on operation. Similarly, the second P-type MOSFET 24 is turned on when the second GaN transistor 22 starts operating, and then, continues the on operation.

FIG. 5 illustrates an example of a case where the first GaN transistor 21 and the second GaN transistor 22 are normally-on type GaN-HEMTs, and the semiconductor device 1 includes the first P-type MOSFET 23 and the second P-type MOSFET 24. The electric circuit achieved by the semiconductor device 1 is not limited to the example of FIG. 5. For example, the set of the first GaN transistor 21 and the first P-type MOSFET 23 may be one GaN transistor. Similarly, the set of the second GaN transistor 22 and the second P-type MOSFET 24 may be one GaN transistor.

According to the semiconductor device 1 according to the first embodiment, it is possible to provide a semiconductor device capable of saving a component space as described below.

As described above, the semiconductor device 1 according to the first embodiment has the capacitor 15 above the GaN transistor group TR (or, in a +Z direction). In a case where the decoupling capacitor of the semiconductor device is arranged in the X-Y plane direction of the GaN transistor group TR (for example, in the +X direction), the semiconductor device may need to enlarge, for example, the package substrate 10, the case 11, the first lead frame 12, the second lead frame 13, and the third lead frame 14 in the +X direction. In other words, the component space in the X-Y plane view (the top view) may increase by an area of the decoupling capacitor, and an area of the entire semiconductor device may increase.

Meanwhile, the semiconductor device 1 has the capacitor 15 functioning as the decoupling capacitor above the GaN transistor group TR, whereby it is possible to save the component space, and reduce a device area in the top view.

Moreover, the semiconductor device 1 has the capacitor 15 above the GaN transistor group TR, whereby it is possible to reduce a ringing peak during switching by using a cancellation effect of a magnetic field.

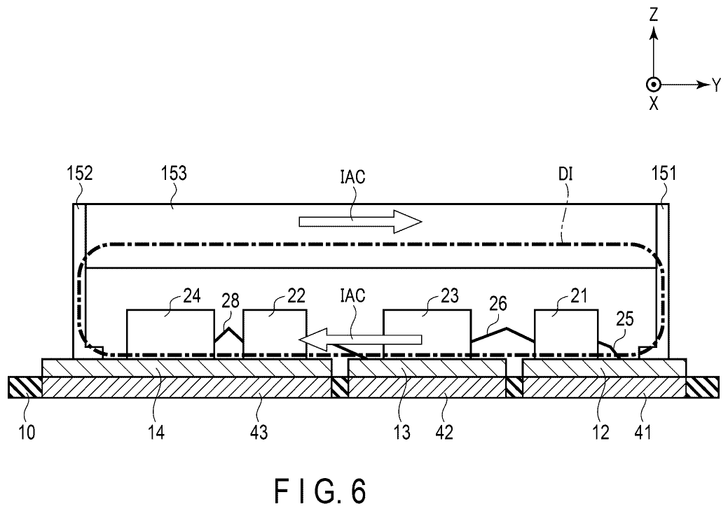

FIG. 6 is the conceptual diagram showing the example of the case where the high-frequency signal is input to the semiconductor device according to the first embodiment. FIG. 6 illustrates a cross section of the same area as in FIG. 3.

A current path DI is an example of a path of a high-frequency current IAC flowing through the device in a case where the high-frequency signal is input to the semiconductor device 1. The current path DI is, for example, an annular path including a path passing through the GaN transistor group TR and the capacitor 15. The high-frequency current IAC loops, for example, through the current path DI. Specifically, for example, the high-frequency current IAC passes and loops through the first GaN transistor 21, the first P-type MOSFET 23, the second GaN transistor 22, the second P-type MOSFET 24, the second terminal 152, the capacitor portion 153, and the first terminal 151 in this order. In other words, the high-frequency current IAC passed through the first terminal 151 flows into the first GaN transistor 21 again.

Such high-frequency current IAC flows, for example, in the +Y direction when passing through the capacitor portion 153, and flows in the −Y direction when passing through the GaN transistor group TR. A magnetic field generated by the high-frequency current IAC flowing in the +Y direction and a magnetic field generated by the high-frequency current IAC flowing in the −Y direction cancel each other. Since the magnetic fields generated when the high-frequency current IAC flows cancel each other, the semiconductor device 1 can reduce the ringing peak generated during the switching. A direction of the loop of the high-frequency current IAC and the like can be changed by a voltage applied to the external connection terminals.

Further, by disposing the decoupling capacitor near the GaN transistor group TR, it is possible to reduce the parasitic inductance, and further reduce the ringing peak. The semiconductor device 1 has the capacitor 15 above the GaN transistor group TR, whereby it is possible to structurally dispose the decoupling capacitor near the GaN transistor group TR, and reduce the ringing peak. In the capacitor 15, the capacitor portion 153 can be disposed near the GaN transistor group TR by adjusting heights of the first terminal 151 and the second terminal 152 in the Z direction. For example, a distance between the capacitor portion 153 and the GaN transistor group TR in the Z direction is a minimum distance at which the capacitor portion 153 does not interfere with the GaN transistor group TR.

Since the capacitor 15 is disposed above the GaN transistor group TR in the semiconductor device 1, the first terminal 151, the second terminal 152, and the capacitor portion 153 have an integrated structure as the capacitor 15. Therefore, the capacitor 15 can be easily connected to the lead frames with electrical stability. Moreover, since the semiconductor device 1 has the first terminal 151 and the second terminal 152 and has a structure in which the capacitor portion 153 is not in contact with the lead frames, resistance to vibration is high and acoustic noise of the capacitor can be suppressed. The capacitor 15 can be disposed at low cost in the semiconductor device 1.

In this way, the semiconductor device 1 has the capacitor 15 above the GaN transistor group TR, whereby it is possible to save the component space while reducing the ringing peak, and reduce the apparatus area. With such design, the semiconductor device 1 can improve a degree of freedom in design and applicability of the device.

In the first embodiment described above, an example has been described in which the width of the capacitor portion 153 in the X direction is equal to or larger than the width of the GaN transistor group TR in the X direction, but the present embodiment is not limited thereto. For example, as long as the reduction of the ringing peak of the semiconductor device 1 is not hindered, the width of the capacitor portion 153 in the X direction may be smaller than the width of the GaN transistor group TR in the X direction. In other words, for example, the capacitor portion 153 may not cover the GaN transistor group TR in the X direction in the X-Y plane view (the top view).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first switch;
a second switch electrically connected to the first switch; and
a capacitor including a first terminal, a second terminal, and a capacitor having an end electrically connected to the first terminal and another end electrically connected to the second terminal, wherein
the first terminal is electrically connected to the first switch,
the second terminal is electrically connected to the second switch,
the capacitor is located above the first switch and the second switch along a first direction,
a width of the capacitor in a second direction that is a direction connecting the end and the another end of the capacitor is larger than a width of a set of the first switch and the second switch in the second direction, and
the first switch and the second switch are arranged in the second direction.

2. The semiconductor device according to claim 1, wherein the width of the set of the first switch and the second switch in the second direction is
a total length of a width of the first switch, a width of the second switch, and a distance between the first switch and the second switch.

3. The semiconductor device according to claim 1, wherein the width of the set of the first switch and the second switch in the second direction is
a distance in the second direction between an end on a side at the second direction of an element among the first and second switches located on a side at the second direction and an end on a side at a third direction of an element among the first and second switches located on the side at the third direction, the third direction being opposite to the second direction.

4. The semiconductor device according to claim 1, further comprising:
a first lead frame having an upper surface on which the first switch and the first terminal are disposed;
a second lead frame having an upper surface on which the second switch and the second terminal are disposed;
a first external connection terminal electrically connected to the first lead frame;
a second external connection terminal electrically connected to the second lead frame; and
a third external connection terminal, wherein
the first switch has an end electrically connected to the first external connection terminal, and another end electrically connected to an end of the second switch and the third external connection terminal,
another end of the second switch is electrically connected to the second external connection terminal,
the first terminal is electrically connected to the end of the first switch, and
the second terminal is electrically connected to the another end of the second switch.

5. The semiconductor device according to claim 1, further comprising:
a first lead frame having an upper surface on which the first switch and the first terminal are disposed;
a second lead frame having an upper surface on which the second switch and the second terminal are disposed;
a third lead frame;
a first external connection terminal electrically connected to the first lead frame;
a second external connection terminal electrically connected to the second lead frame;
a third external connection terminal electrically connected to the third lead frame;
a first MOSFET disposed on the third lead frame; and
a second MOSFET disposed on the second lead frame, wherein
the first switch has an end electrically connected to the first external connection terminal, and another end electrically connected to an end of the first MOSFET,
another end of the first MOSFET is electrically connected to a control terminal of the first switch, an end of the second switch, and the third external connection terminal,
another end of the second switch is electrically connected to an end of the second MOSFET,
another end of the second MOSFET is electrically connected to a control terminal of the second switch and the second external connection terminal,
the first terminal is electrically connected to the end of the first switch,
the second terminal is electrically connected to the another end of the second MOSFET,
a width of the capacitor in the second direction is larger than a width of a set of the first switch, the first MOSFET, the second switch, and the second MOSFET in the second direction,
the first switch, the first MOSFET, the second switch, and the second MOSFET are arranged in the second direction, and
the first switch and the second switch are GaN transistors.

6. The semiconductor device according to claim 5, wherein the width of the set of the first switch, the first MOSFET, the second switch, and the second MOSFET in the second direction is
a distance in the second direction between an end on a side at the second direction of one of the first and second switches and the first and second MOSFETs located farthest in the second direction and an end on a side at a third direction of one of the first and second switches and the first and second MOSFETs located farthest in the third direction, the third direction being opposite to the second direction.

7. The semiconductor device according to claim 5, wherein the width of the set of the first switch, the first MOSFET, the second switch, and the second MOSFET in the second direction is
a total length of respective widths in the second direction of the first and second switches and the first and second MOSFETs and a distance in the second direction between every adjacent two of the first and second switches and the first and second MOSFETS.

8. The semiconductor device according to claim 5, wherein the width of the set of the first switch, the first MOSFET, the second switch, and the second MOSFET in the second direction is
a total length of respective widths in the second direction of the first and second switches and the first and second MOSFETs, a distance in the second direction between the first switch and the first MOSFET, a distance in the second direction between the first MOSFET and the second switch, and a distance in the second direction between the second switch and the second MOSFET.

9. The semiconductor device according to claim 1, wherein the first switch and the second switch are GaN transistors.

10. The semiconductor device according to claim 1, wherein the capacitor is a multi-layer ceramic capacitor (MLCC).

11. The semiconductor device according to claim 1, wherein a width of the capacitor in a fourth direction intersecting the first direction and the second direction is equal to or larger than a width of a set of the first switch and the second switch in the fourth direction.

12. The semiconductor device according to claim 11, wherein the width of the set of the first switch and the second switch in the fourth direction is
a distance in the fourth direction between an end on a side at the fourth direction of one of the first and second switches located on the side at the fourth direction and an end on a side at a fifth direction of one of the first and second switches located on the side at the fifth direction, the fifth direction being opposite to the fourth direction.

13. The semiconductor device according to claim 1, further comprising:
a first control device that controls the first switch; and
a second control device that controls the second switch.

14. The semiconductor device according to claim 4, further comprising:
a first control device that controls the first switch;
a second control device that controls the second switch; and
a resin that covers the first switch, the second switch, the capacitor, the first lead frame, the second lead frame, the first control device, and the second control device.

15. The semiconductor device according to claim 11, wherein in a top view, the capacitor covers the first switch and the second switch.
